(19) United States
(12) Patent Application Publication
(10) Pub. No.: US 2024/0093042 A1
(43) Pub. Date: Mar. 21, 2024

(54) INK COMPOSITION, LAYER USING THE SAME, ELECTROPHORESIS DEVICE AND DISPLAY DEVICE COMPRISING THE SAME

(71) Applicant: Samsung Display Co., LTD., Yongin-si (KR)

(72) Inventors: Janghyuk KIM, Yongin-si (KR); Jinsuop YOUN, Yongin-si (KR); Kyuyoung KIM, Yongin-si (KR); MISUN KIM, Yongin-si (KR); Minjun KIM, Yongin-si (KR); BONGYONG KIM, Yongin-si (KR); YoungMin KIM, Yongin-si (KR); CHULJIN PARK, Yongin-si (KR); Heeje WOO, Yongin-si (KR); JEONGWOO LEE, Yongin-si (KR); HYUNMOO CHOI, Yongin-si (KR)

(73) Assignee: Samsung Display Co., LTD., Yongin-si (KR)

(21) Appl. No.: 18/461,070

(22) Filed: Sep. 5, 2023

(30) Foreign Application Priority Data
Sep. 6, 2022 (KR) 10-2022-0112918

(51) Int. Cl. C09D 5/44; C09D 11/033; C09D 11/037; G02F 1/167; H01L 25/075; H01L 33/32

(52) U.S. Cl. CPC C09D 5/448; C09D 11/033; C09D 11/037; G02F 1/167; H01L 25/0753; H01L 33/32

(57) ABSTRACT

Embodiments provide an ink composition, a layer manufactured using the ink composition, an electrophoresis device including the layer, and a display device including the layer. The ink composition includes a semiconductor nanorod, and a solvent that satisfies Equation 1:

|ε1−ε2|/ε1*100≤10 [Equation 1]

In Equation 1, ε1 is a dielectric constant of the solvent at 50 Hz, and ε2 is a dielectric constant of the solvent at 50 kHz.

### CROSS-REFERENCE TO RELATED APPLICATION(S)

This application claims priority to and benefits of Korean Patent Application No. 10-2022-0112918 under 35 U.S.C. § 119, filed on Sep. 6, 2022, in the Korean Intellectual Property Office, the entire contents of which are incorporated herein by reference.

### BACKGROUND

### 1. Technical Field

The disclosure relates to an ink composition, a layer using the same, an electrophoresis device, and a display device including the same.

### 2. Description of the Related Art

Light emitting devices (LEDs) have been actively developed since 1992 when Nakamura and others from Japanese Nichia Corp. succeeded in fusing a high-quality single crystal GaN nitride semiconductor by applying a low temperature GaN compound buffer layer. An LED is a semiconductor device that converts electric signals into light having wavelengths in a desired region by using characteristics of a compound semiconductor, which has a structure in which an n-type semiconductor crystal in which carriers are electrons and a p-type semiconductor crystal in which carriers are holes, are combined with each other.

LEDs have high light conversion efficiency and thus consume very little energy and have a semi-permanent lifespan, and is also environmentally friendly and is thus called revolutionary as a green material. Recently, high luminance red, orange, green, blue, and white LEDs have been developed with the development of compound semiconductor technology and are being applied in many fields such as traffic lights, mobile phones, car headlights, outdoor billboards, an LCD back light unit (BLU), and indoor/outdoor lighting, which keeps being actively researched at home and abroad. For example, a GaN-based compound semiconductor having a wide bandgap may be a material used to manufacture an LED semiconductor emitting light in green, blue, and ultraviolet (UV) regions, and since a blue LED device may be used to manufacture a white LED device, a great deal of research is being conducting on this technology.

Studies on ultra-small LED devices having a nano or micro unit size are being actively conducted, and in addition studies for utilizing these ultra-small LED devices in lighting and displays are being continuously conducted. In these studies, electrodes capable of applying power to the ultra-small LED devices, disposition of the electrodes for reducing a space occupied by the electrodes, a method of mounting the ultra-small LED devices on the disposed electrodes, and the like are continuously attracting attention.

The method of mounting the ultra-small LED devices on the disposed electrodes may still have difficulties of disposing and mounting the ultra-small LED devices on the electrodes as intended due to size limitations of the ultra-small LED devices. Ultra-small LED devices may have a nano-scale or micro-scale and thus may not be disposed by hand one by one on a target electrode region.

Recently, as a demand for nanoscale ultra-small LED devices is increasing, attempts have been made to develop a nanoscale GaN-based compound semiconductor or an InGaN-based compound semiconductor into light emitting devices by making the nano-scale GaN-based compound semiconductor or InGaN-based compound semiconductor into nano rods and aligning the nano rods regularly. Among them, the alignment of an InGaN nanorod (NED) LED by using an electric field (electrophoresis or dielectrophoresis) has drawn attention as a method for significantly reducing a complex and expensive process cost of μ-LEDs, mini-LEDs, and the like.

A force of this electrophoresis or dielectrophoresis may be affected by dielectric characteristics of particles and a solvent exposed to the electric field and the like, but heretofore, an appropriate range of parameters in the alignment of InGaN nanorod LED (NED) may not be introduced at all.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An embodiment provides an ink composition having excellent electrophoretic characteristics of semiconductor nanorods.

Another embodiment provides a layer manufactured using the ink composition.

Another embodiment provides an electrophoretic device and a display device including the layer.

An embodiment provides an ink composition which may include: a semiconductor nanorod; and a solvent that satisfies Equation 1:

|ε1−ε2|/ε1*100≤10 [Equation 1]

In Equation 1,
ε1 is a dielectric constant of the solvent at 50 Hz, and
ε2 is a dielectric constant of the solvent at 50 kHz.

In an embodiment, the solvent may satisfy Equation 2:

|ε1−ε2|/ε1*100≤5 [Equation 2]

In Equation 2,
ε1 is a dielectric constant of the solvent at 50 Hz, and
ε2 is a dielectric constant of the solvent at 50 kHz.

In an embodiment, the solvent may be a single non-citrate-based compound.

In an embodiment, the solvent may include at least two compounds.

In an embodiment, the solvent may include at least three compounds.

In an embodiment, the semiconductor nanorod may have a diameter in a range of about 300 nm to about 900 nm.

In an embodiment, the semiconductor nanorod may have a length in a range of about 3.5 μm to about 6 μm.

In an embodiment, the semiconductor nanorod may include a GaN-based compound, an InGaN-based compound, or a combination thereof.

In an embodiment, the semiconductor nanorod may have a surface coated with a metal oxide.

In an embodiment, the metal oxide may include alumina, silica, or a combination thereof.

In an embodiment, an amount of the semiconductor nanorod in the ink composition may be in a range of about 0.01 wt % to about 10 wt %, based on a total amount of the ink composition.

In an embodiment, the ink composition may include malonic acid, 3-amino-1,2-propanediol, a silane-based coupling agent, a leveling agent, a fluorine-based surfactant, or a combination thereof.

In an embodiment, the ink composition may be an ink composition for an electrophoresis device.

In an embodiment, a layer may be manufactured using the ink composition.

In an embodiment, an electrophoresis device may include the layer manufactured using the ink composition.

In an embodiment, a display device may include the layer manufactured using the ink composition.

Other embodiments may be included in the following detailed description.

The ink composition including the semiconductor nanorods may provide an ink composition having excellent electrophoretic characteristics and realization of a high degree of alignment.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic cross-sectional view of a semiconductor nanorod used in a curable composition according to an embodiment.

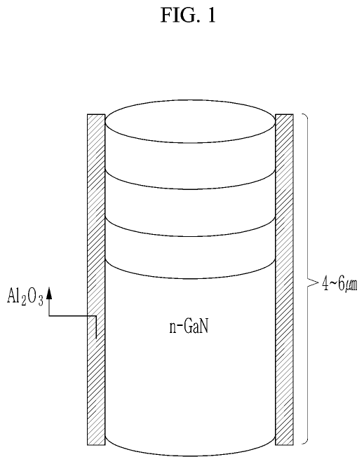

FIG. 2 is a graph showing a change trend of a real part (ε′r) and an imaginary part (ε″r) of a dielectric constant of a solvent according to a frequency according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

In the specification, the word “on” or “above” means positioned or disposed on or below the object portion, and does not necessarily mean positioned or disposed on the upper side of the object portion based on a gravitational direction.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, 10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

As used herein, when a specific definition is not otherwise provided, an “alkyl group” refers to a C1 to C20 alkyl group, an “alkenyl group” refers to a C2 to C20 alkenyl group, a “cycloalkenyl group” refers to a C3 to C20 cycloalkenyl group, a “heterocycloalkenyl group” refers to a C3 to C20 heterocycloalkenyl group, an “aryl group” refers to a C6 to C20 aryl group, an “arylalkyl group” refers to a C6 to C20 arylalkyl group, an “alkylene group” refers to a C1 to C20 alkylene group, an “arylene group” refers to a C6 to C20 arylene group, an “alkylarylene group” refers to a C6 to C20 alkylarylene group, a “heteroarylene group” refers to a C3 to C20 heteroarylene group, and a “alkoxylene group” refers to a C1 to C20 alkoxylene group.

As used herein, when a specific definition is not otherwise provided, “substituted” may refer to substitution with a halogen atom (F, Cl, Br, I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or any combination thereof, instead of at least one hydrogen.

As used herein, when a specific definition is not otherwise provided, “hetero” may refer to one substituted with at least one heteroatom of N, O, S, or P in a chemical formula.

As used herein, when a specific definition is not otherwise provided, “(meth)acrylate” may refer to both “acrylate” and “methacrylate,” and “(meth)acryl-based” may refer to both “acryl-based” and “methacryl-based.”

As used herein, when a specific definition is not otherwise provided, the term “combination” may refer to mixing or copolymerization.

As used herein, unless a specific definition is otherwise provided, a hydrogen atom may be bonded at a position when a chemical bond is not drawn where it is supposed to be given.

In this specification, a semiconductor nanorod may refer to a rod-shaped semiconductor having a nano-sized diameter.

As used herein, when a specific definition is not otherwise provided, the symbol “*” represents a bonding site to a neighboring atom in a corresponding formula or moiety.

An ink composition according to an embodiment may include: a semiconductor nanorod; and a solvent that satisfies Equation 1.

|ε1−ε2|/ε1*100≤10 [Equation 1]

In Equation 1,
ε1 is a dielectric constant of the solvent at 50 Hz, and
ε2 is a dielectric constant of the solvent at 50 kHz.

In an embodiment, the solvent may satisfy Equation 2.

|ε1−ε2|/ε1*100≤5 [Equation 2]

In Equation 2,
ε1 is a dielectric constant of the solvent at 50 Hz, and
ε2 is a dielectric constant of the solvent at 50 kHz.

However, organic solvents (PGMEA, GBL, PGME, ethyl acetate, IPA, and the like) which are conventionally used in display and electronic technologies have low viscosity and therefore inorganic nanorod particles having a high density may be sedimented too quickly and thus agglomerate. Such organic solvents may quickly volatize and thus contribute to poor alignment characteristics during a solvent drying step after dielectrophoresis. In the related art, there has been an effort to discover a novel solvent. However, embodiments provide limiting a dielectric constant of a solvent in the ink composition within a specific range, thereby improving alignment characteristics of semiconductor nanorods.

Signals of various waveforms and frequencies rather than alternating current (AC) signals of simple waveforms may be applied in a complex manner in order to precisely control and constantly align semiconductor nanorods between electrodes. However, when the signals of various frequencies are applied, electric characteristics such as a dielectric constant may be changed by molecular structure characteristics of the solvent, impurities, and the like.

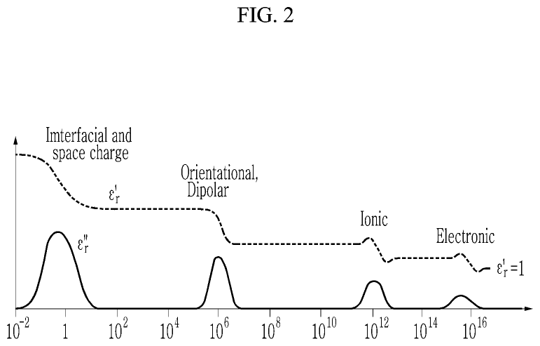

A phenomenon in which a dielectric constant decreases as a frequency increases is called a dielectric loss, wherein this dielectric loss phenomenon may be caused by interfacial and space charge; or may be caused by orientational polarization, dipolar polarization, ionic polarization, or electronic polarization of the solvent (see FIG. 2). The dielectric loss phenomenon may cause energy of the electric field applied to the solvent to be lost into heat energy and cause deterioration of the alignment of semiconductor nanorods by weakening energy of AC signals which are applied during the alignment of semiconductor nanorods.

Hereinafter, each component is described in detail.

[Semiconductor Nanorod]

As dispersion stability of an ink composition including semiconductor nanorods and a solvent may be increased, large area inkjetting and dielectrophoresis processability may be improved.

The semiconductor nanorod may include a GaN-based compound, an InGaN-based compound, or a combination thereof, and may have a surface coated with a metal oxide.

To ensure dispersion stability of the semiconductor nanorod ink solution (semiconductor nanorod plus solvent), a time of about 3 hours may be required, which may be insufficient to perform a large-area inkjet process. However, by coating the surface of the semiconductor nanorod with a metal oxide including alumina, silica, or any combination thereof to form a coating layer or an insulating layer (Al₂O₃ or SiOₓ), compatibility with a solvent described later may be maximized.

In an embodiment, the coating layer or insulating layer coated with the metal oxide may have a thickness in a range of about 40 nm to about 60 nm.

In an embodiment, a functional group such as a siloxane group may be bonded to a metal oxide coating layer or insulating layer on the surface of the semiconductor nanorod. Since the compatibility with the solvent (as described below) is increased, both the dispersion stability of the semiconductor nanorods and the dielectrophoretic characteristics of the ink composition may be improved.

The semiconductor nanorod may include an n-type confinement layer and a p-type confinement layer, and a multiquantum well (MQW) active portion (that is, an MQW active region) may be located between the n-type confinement layer and the p-type confinement layer.

In an embodiment, the semiconductor nanorod may have a diameter in a range of about 300 nm to about 900 nm. In an embodiment, the semiconductor nanorod may have a diameter in a range of about 600 nm to about 800 nm.

In an embodiment, the semiconductor nanorod may have a length in a range of about 3.5 μm to about 6 μm. In an embodiment, the semiconductor nanorod may have a length in a range of about 3.5 μm to about 5 μm.

In an embodiment, when the semiconductor nanorod includes an alumina insulating layer, it may have a density of about 5 g/cm³ to about 6 g/cm³.

In an embodiment, the semiconductor nanorod may have a mass in a range of about 1×10⁻¹³ g to about 1×10⁻¹¹ g.

When the semiconductor nanorod have the above diameter, length, density, and type, surface coating of the metal oxide may be facilitated, and dispersion stability of the semiconductor nanorods may be maximized.

An amount of the semiconductor nanorod in the ink composition may be in a range of about 0.01 wt % to about 10 wt % based on a total amount of the ink composition. In an embodiment an amount of the semiconductor nanorod in the ink composition may be in a range of about 0.01 wt % to about 5 wt %, based on a total amount of the ink composition. In an embodiment, an amount of the semiconductor nanorod in the ink composition may be in a range of about 0.01 parts by weight to about 0.5 parts by weight, based on 100 parts by weight of the solvent in the ink composition. In an embodiment, an amount of the semiconductor nanorod in the ink composition may be in a range of about 0.01 parts by weight to about 0.1 parts by weight, based on 100 parts by weight of the solvent in the ink composition. When an amount of the semiconductor nanorod in the ink composition is within the above ranges, dispersibility in the ink may be good, and the manufactured pattern may have excellent luminance.

[Solvent]

In an embodiment, a degree of biased alignment of semiconductor nanorods using dielectrophoresis or electrophoresis may be improved by introducing a solvent having a change of less than about 10% in a dielectric constant according to a frequency into an ink composition. In an embodiment, a degree of biased alignment of semiconductor nanorods using dielectrophoresis or electrophoresis may be improved by introducing a solvent having a change of less than about 5% in a dielectric constant according to a frequency into an ink composition.

In an embodiment, a solvent having a change of less than about 10% in a dielectric constant according to a frequency may be represented by Equation 1. In an embodiment, a solvent having a change of less than 5% in a dielectric constant according to a frequency may be represented by Equation 2.

When a difference between a dielectric constant at about 50 Hz and a dielectric constant at about 50 kHz is less than about 10% in a solvent, a high degree of alignment of the semiconductor nanorods in the solvent may be achieved. When a difference between a dielectric constant at about 50 Hz and a dielectric constant at about 50 kHz is less than about 5% in a solvent, a high degree of alignment of the semiconductor nanorods in the solvent may be achieved. However, when a difference between a dielectric constant at about 0 Hz and a dielectric constant at about 50 kHz is greater than about 10% in a solvent, a high degree of alignment of the semiconductor nanorods in the solvent may not be realized.

In an embodiment, the solvent may be a single non-citrate-based compound, but the solvent is not necessarily limited thereto. However, when the solvent is a single citrate-based compound, the solvent may not satisfy Equations 1 and 2, and the high degree of alignment of the semiconductor nanorods may be difficult to realize.

In an embodiment, the solvent may include at least two compounds. In an embodiment, the solvent may include at least three compounds. In an embodiment, when the solvent is a mixture of at least two compounds, the citrate-based compound may be included. However, although the mixture may include the citrate-based compound, it may be possible to readily control a change in a dielectric constant according to a frequency of the mixed solvent by an interaction with other compounds within about 10%. However, although the mixture may include the citrate-based compound, it may be possible to readily control a change in a dielectric constant according to a frequency of the mixed solvent by an interaction with other compounds within about 5%.

In an embodiment, the solvent may have a viscosity of at least about 3 cps at 50° C.

In an embodiment, the citrate-based compound may be represented by Chemical Formula 3.

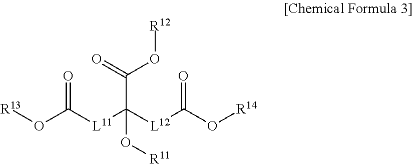

In Chemical Formula 3,
R¹¹ may be a hydrogen atom or *—C(═O)R′ (wherein R′ may be a hydrogen atom or a substituted or unsubstituted C1 to C10 alkyl group),
R¹² to R¹⁴ may each independently be a substituted or unsubstituted C2 to C20 alkyl group, and
L¹¹ and L¹² may each independently be a substituted or unsubstituted C1 to C20 alkylene group.

For example, a single non-citrate-based compound may include a compound that is not represented by Chemical Formula 3.

For example, the compound represented by Chemical Formula 3 may include a compound represented by Chemical Formula 3-1 or Chemical Formula 3-2.

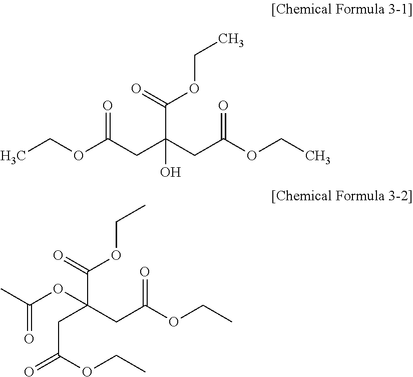

For example, an amount of the solvent in the ink composition may be in a range of about 5 wt % to about 99.99 wt %, based on a total amount of the ink composition. For example, an amount of the solvent in the ink composition may be in a range of about 20 wt % to about 99.95 wt %, based on a total amount of the ink composition. For example, an amount of the solvent in the ink composition may be in a range of about 90 wt % to about 99.99 wt %, based on a total amount of the ink composition.

[Polymerizable Monomer]

The ink composition according to an embodiment may further include a polymerizable compound, if necessary. The polymerizable compound may be used by mixing monomers or oligomers commonly used in conventional curable compositions.

For example, the polymerizable compound may be a polymerizable monomer having a carbon-carbon double bond at its terminal end.

For example, the polymerizable compound may be a polymerizable monomer having at least one functional group represented by Chemical Formula A-1 or a functional group represented by Chemical Formula A-2 at its terminal end.

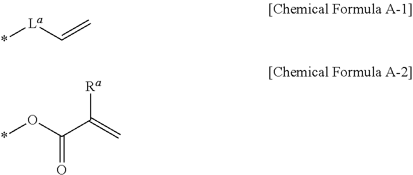

In Chemical Formula A-1 and Chemical Formula A-2,

L^{a} may be a substituted or unsubstituted C1 to C20 alkylene group, and

R^{a} may be a hydrogen atom or a substituted or unsubstituted C1 to C20 alkyl group.

The polymerizable compound may include at least one carbon-carbon double bond at a terminal end. For example, a functional group represented by Chemical Formula A-1 or a functional group represented by Chemical Formula A-2, thereby forming a crosslinked structure with the surface-modifying compound. The crosslinked body thus formed may further enhance dispersion stability of the semiconductor nanorods by further doubling a type of steric hindrance effect.

For example, the polymerizable compound including at least one functional group represented by Chemical Formula A-1 at the terminal end may include divinyl benzene, triallyl cyanurate, triallyl isocyanurate, triallyl trimellitate, triallyl phosphate, triallyl phosphite, triallyl triazine, diallyl phthalate, or any combination thereof, but is not necessarily limited thereto.

For example, the polymerizable compound including at least one functional group represented by Chemical Formula A-2 at the terminal end may include ethylene glycol diacrylate, triethylene glycol diacrylate, 1,4-butanediol diacrylate, 1,6-hexane diol diacrylate, neopentyl glycol diacrylate, pentaerythritol diacrylate, pentaerythritol triacrylate, dipentaerythritol diacrylate, dipentaerythritol triacrylate, dipentaerythritol pentaacrylate, pentaerythritol hexaacrylate, bisphenol A diacrylate, trimethylolpropane triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, 1,6-hexanediol dimethacrylate, polyfunctional epoxy (meth)acrylate, polyfunctional urethane (meth)acrylate, KAYARAD DPCA-20, KAYARAD DPCA-30, KAYARAD DPCA-60, KAYARAD DPCA-120, or KAYARAD DPEA-12 of Nippon Chemical Co., Ltd., or any combination thereof, but is not necessarily limited thereto.

The polymerizable compound may be used after being treated with an acid anhydride to impart better developability.

[Polymerization Initiator]

The ink composition according to an embodiment may further include a polymerization initiator, for example, a photopolymerization initiator, a thermal polymerization initiator, or any combination thereof, if necessary.

The photopolymerization initiator may be an initiator for a curable composition and may include, for example, an acetophenone-based compound, a benzophenone-based compound, a thioxanthone-based compound, a benzoin-based compound, a triazine-based compound, an oxime-based compound, an aminoketone-based compound, and the like, but is not necessarily limited thereto.

Examples of an acetophenone-based compound may include 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of a benzophenone-based compound may include benzophenone, benzoyl benzoate, benzoyl methyl benzoate, 4-phenyl benzophenone, hydroxybenzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of a thioxanthone-based compound may include thioxanthone, 2-methylthioxanthone, isopropyl thioxanthone, 2,4-diethyl thioxanthone, 2,4-diisopropyl thioxanthone, 2-chlorothioxanthone, and the like.

Examples of a benzoin-based compound may include benzoin, benzoin methyl ether, benzoin ethyl ether, benzoin isopropyl ether, benzoin isobutyl ether, benzyldimethylketal, and the like.

Examples of a triazine-based compound may include 2,4,6-trichloro-s-triazine, 2-phenyl-4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl-4,6-bis(trichloro methyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of an oxime-based compound may include an O-acyloxime-based compound, 2-(O-benzoyloxime)-1-[4-(phenylthio)phenyl]-1,2-octandione, 1-(0-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Examples of the O-acyloxime-based compound may be 1,2-octandione, 2-dimethylamino-2-(4-methylbenzyl)-1-(4-morpholin-4-yl-phenyl)-butan-1-one, 1-(4-phenylsulfanyl phenyl)-butane-1,2-dione-2-oxime-O-benzoate, 1-(4-phenylsulfanyl phenyl)-octane-1,2-dione-2-oxime-O-benzoate, 1-(4-phenylsulfanyl phenyl)-octan-1-oneoxime-O-acetate, 1-(4-phenylsulfanyl phenyl)-butan-1-oneoxime-O-acetate, and the like.

Examples of an aminoketone-based compound may include 2-benzyl-2-dimethylamino-1-(4-morpholinophenyl)-butanone-1, and the like.

The photopolymerization initiator may further include a carbazole-based compound, a diketone-based compound, a sulfonium borate-based compound, a diazo-based compound, an imidazole-based compound, a biimidazole-based compound, and the like, besides the compounds.

The photopolymerization initiator may be used with a photosensitizer capable of causing a chemical reaction by absorbing light and becoming excited and transferring its energy.

Examples of a photosensitizer may include tetraethylene glycol bis-3-mercapto propionate, pentaerythritol tetrakis-3-mercapto propionate, dipentaerythritol tetrakis-3-mercapto propionate, and the like.

The thermal polymerization initiator may include a peroxide, and examples thereof may include benzoyl peroxide, dibenzoyl peroxide, lauryl peroxide, dilauryl peroxide, di-tert-butyl peroxide, cyclohexane peroxide, methyl ethyl ketone peroxide, oxides, hydroperoxide (e.g., tert-butyl hydroperoxide, cumene hydroperoxide, etc.), dicyclohexyl peroxydicarbonate, 2,2-azo-bis(isobutyronitrile), t-butyl perbenzoate, 2,2′-azobis-2-methylpropionitrile, etc., but are not necessarily limited thereto, and any one in the related art may be used.

An amount of the polymerization initiator may be in a range of about 1 wt % to about 5 wt %, based on a total amount of solid components constituting the ink composition. For example, an amount of the polymerization initiator may be in a range of about 2 wt % to about 4 wt %, based on the total amount of solid components constituting the ink composition. When the polymerization initiator is included within any of the above ranges, excellent reliability may be obtained due to sufficient curing during exposure or thermal curing.

[Other Additives]

The ink composition according to an embodiment may further include a polymerization inhibitor including a hydroquinone-based compound, a catechol-based compound, or any combination thereof, as needed. As the ink composition according to an embodiment further includes the hydroquinone-based compound, the catechol-based compound, or any combination thereof, crosslinking at room temperature may be prevented during exposure after printing (coating) the ink composition.

For example, the hydroquinone-based compound, the catechol-based compound, or the combination thereof may include hydroquinone, methyl hydroquinone, methoxyhydroquinone, t-butyl hydroquinone, 2,5-di-t-butyl hydroquinone, 2,5-bis(1,1-dimethylbutyl) hydroquinone, 2,5-bis (1,1,3,3-tetramethylbutyl) hydroquinone, catechol, t-butyl catechol, 4-methoxyphenol, pyrogallol, 2,6-di-t-butyl-4-methylphenol, 2-naphthol, tris(N-hydroxy-N-nitrosophenylaminato-O,O′)aluminum, or any combination thereof, but are not necessarily limited thereto.

The hydroquinone-based compound, catechol-based compound, or combination thereof may be used in a form of dispersion, and an amount of the polymerization inhibitor in a form of the dispersion may be in a range of about 0.001 wt % to about 1 wt %, based on a total amount of the ink composition. For example, an amount of the polymerization inhibitor in a form of the dispersion may be in a range of about 0.01 wt % to about 0.1 wt %, based on a total amount of the ink composition. When the polymerization inhibitor is included within any of the above ranges, issues associated with the passage of time at room temperature may be solved and sensitivity deterioration and surface delamination phenomenon may be inhibited.

In an embodiment, the ink composition may include malonic acid, 3-amino-1,2-propanediol, a silane-based coupling agent, a leveling agent, a fluorine-based surfactant, or any combination thereof, in addition to the polymerization inhibitor, as needed.

For example, the ink composition may further include a silane-based coupling agent having a reactive substituent such as a vinyl group, a carboxyl group, a methacryloxy group, an isocyanate group, an epoxy group, and the like in order to improve close contacting properties with a substrate.

Examples of a silane-based coupling agent may include trimethoxysilyl benzoic acid, γ-methacryl oxypropyl trimethoxysilane, vinyl triacetoxysilane, vinyl trimethoxysilane, γ-isocyanate propyl triethoxysilane, γ-glycidoxy propyl trimethoxysilane, β-(epoxycyclohexyl)ethyltrimethoxysilane, and the like, and these may be used alone or in a mixture of at least two.

The silane-based coupling agent may be used in an amount in a range of about 0.01 parts by weight to about 10 parts by weight, based on 100 parts by weight of the ink composition. When the silane-based coupling agent is included within the range, close contacting properties, storage capability, and the like may be improved.

The ink composition may further include a surfactant, such as a fluorine-based surfactant, to improve coating properties and prevent defect formation, if necessary.

Examples of a fluorine-based surfactant may include BM-1000®, BM-1100@, and the like of BM Chemie Inc.; MEGAFACE F 142D®, MEGAFACE F 172®, MEGAFACE F 173®, MEGAFACE F 183®, and the like of Dainippon Ink Kagaku Kogyo Co., Ltd.; FULORAD FC-135®, FULORAD FC-170C®, FULORAD FC-430®, FULORAD FC-431®, and the like of Sumitomo 3M Co., Ltd.; SURFLON S-112®, SURFLON S-113®, SURFLON S-131®, SURFLON S-141®, SURFLON S-145®, and the like of ASAHI Glass Co., Ltd.; SH-28PA®, SH-190®, SH-193®, SZ-6032®, SF-8428®, and the like of Toray Silicone Co., Ltd.; F-482, F-484, F-478, F-554, and the like of DIC Co., Ltd.

An amount of the fluorine-based surfactant may be in a range of about 0.001 parts by weight to about 5 parts by weight, based on 100 parts by weight of the ink composition. When the fluorine-based surfactant is included within the above range, coating uniformity may be secured, stains do not occur, and wettability to a glass substrate may be excellent.

The ink composition may further include other additives such as an antioxidant, a stabilizer, and the like in an amount (e.g., a predetermined or a selectable amount), unless properties are deteriorated.

In an embodiment, the ink composition may be an ink composition for an electrophoresis device.

In an embodiment, a layer which may be manufactured using the ink composition.

An embodiment provides an electrophoresis device which may include the layer.

An embodiment provides a display device which may include the layer.

Hereinafter, embodiments are illustrated in more detail with reference to examples. These examples, however, are not to be interpreted as limiting the scope of the disclosure.

### Preparation of Ink Compositions

### Comparative Example 1

40 ml of hexyl trimethoxysilane (CAS #: 3069-19-0, HSCA, 1.5 mM solution in dodecane) as a ligand is reacted on a nanorod-patterned GaN wafer (4 inches) at room temperature for 15 hours. After the reaction, the wafer is dipped in 50 ml of acetone for 5 minutes to remove excess ligand, and additionally, the wafer surface is rinsed by using 40 ml of acetone. The washed wafer is placed along with 35 ml of GBL in a 27 kW bath-type sonicator and sonicated for 5 minutes to separate the rods from the wafer surface. The separated rods are put in a FALCON tube for centrifugation, and 10 ml of GBL is added thereto to additionally wash the rods on the bath surface. After discarding a supernatant through the centrifugation at 4000 rpm for 10 minutes, precipitates are redispersed in 40 ml of acetone and then passed through a 10 μm mesh filter to filter out foreign matters. After additional centrifugation (4000 rpm, 10 minutes), the precipitates are dried in a drying oven (100° C., 1 hour) and weighed, so that 0.05 w/w % thereof are dispersed in triethyl 2-acetyl citrate (TEC-Ac) as a solvent, preparing an ink composition.

### Comparative Example 2

An ink composition is prepared in the same manner as in Comparative Example 1 except that tributyl citrate is used instead of triethyl 2-acetyl citrate (TEC-Ac) as a solvent.

### Comparative Example 3

An ink composition is prepared in the same manner as in Comparative Example 1 except that diethylene glycol monophenyl ether is used instead of triethyl 2-acetyl citrate (TEC-Ac) as a solvent.

### Example 1

An ink composition is prepared in the same manner as in Comparative Example 1 except that triacetin is used instead of triethyl 2-acetyl citrate (TEC-Ac) as a solvent.

### Example 2

An ink composition is prepared in the same manner as in Comparative Example 1 except that 1-(2-methoxyphenoxy)-2-propanol and diethyl terephthalate are used instead of triethyl 2-acetyl citrate (TEC-Ac) as a solvent.

### Example 3

An ink composition is prepared in the same manner as in Comparative Example 1 except that triethyl citrate and tri-n-propyl-isocyanaurate are used instead of triethyl 2-acetyl citrate (TEC-Ac) as a solvent.

### Example 4

An ink composition is prepared in the same manner as in Comparative Example 1 except that triethyl citrate, 2-ethyl-1,3-hexanediol, and tri-n-propyl-isocyanaurate are used instead of triethyl 2-acetyl citrate (TEC-Ac) as a solvent.

### Example 5

An ink composition is prepared in the same manner as in Comparative Example 1 except that triethyl citrate, diethyl L-tartrate, and triallyl isocyanaurate are used instead of triethyl 2-acetyl citrate (TEC-Ac) as a solvent.

[Evaluation]

The ink compositions according to Examples 1 to 5 and Comparative Examples 1 to 3 are evaluated with respect to a dielectric constant and a change according to a frequency of a solvent, which are shown in Table 1, and in addition, evaluated with respect to dielectrophoretic/electrophoretic characteristics by using Turbiscan. The results are shown in Table 1.

TABLE 1

| | Dielectric constant according to | | | Degree of dielectrophoresis/ | |
|---|---|---|---|---|---|
| | frequency (∈r) | | | electrophoresis alignment | |
| | | | Change amount (Δ) | Center | Biased |
| | 50 Hz | 50 KHz | (\|∈1 − ∈2\|/ | alignment | alignment |
| | ∈1 | ∈2 | ∈1 * 100) | (%) | (%) |
| Comparative | 7.99 | 6.95 | 13% | 83 | 76 |
| Example 1 | | | | | |
| Comparative | 6.91 | 6.21 | 10.1% | 80 | 88 |
| Example 2 | | | | | |
| Comparative | 10.46 | 9.21 | 12% | 85 | 74 |
| Example 3 | | | | | |
| Example 1 | 6.04 | 5.88 | 3% | 89 | 94 |
| Example 2 | 6.64 | 6.24 | 6% | 87 | 91 |
| Example 3 | 5.98 | 5.66 | 5% | 82 | 95 |
| Example 4 | 5.61 | 5.50 | 2% | 92 | 95 |
| Example 5 | 6.52 | 6.43 | 1% | 93 | 96 |

Referring to Table 1, the ink compositions including a solvent not satisfying Equation 1 (Comparative Examples 1 to 3) exhibit insufficient alignment characteristics and thus exhibit inferior dielectrophoretic characteristics compared to the ink compositions including a solvent satisfying Equation 1 (Examples 1 to 5).

Embodiments have been disclosed herein, and although terms are employed, they are used and are to be interpreted in a generic and descriptive sense only and not for the purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. An ink composition, comprising:
a semiconductor nanorod; and
a solvent that satisfies Equation 1:

|ε1−ε2|/ε1*100≤10 [Equation 1]
wherein in Equation 1,
ε1 is a dielectric constant of the solvent at 50 Hz, and
ε2 is a dielectric constant of the solvent at 50 kHz.

2. The ink composition of claim 1, wherein the solvent satisfies Equation 2:

|ε1−ε2|/ε1*100≤5 [Equation 2]
wherein in Equation 2,
ε1 is a dielectric constant of the solvent at 50 Hz, and
ε2 is a dielectric constant of the solvent at 50 kHz.

3. The ink composition of claim 1, wherein the solvent is a single non-citrate-based compound.

4. The ink composition of claim 1, wherein the solvent includes at least two compounds.

5. The ink composition of claim 1, wherein the solvent includes at least three compounds.

6. The ink composition of claim 1, wherein the semiconductor nanorod has a diameter in a range of about 300 nm to about 900 nm.

7. The ink composition of claim 1, wherein the semiconductor nanorod has a length in a range of about 3.5 μm to about 6 μm.

8. The ink composition of claim 1, wherein the semiconductor nanorod includes a GaN-based compound, an InGaN-based compound, or a combination thereof.

9. The ink composition of claim 1, wherein the semiconductor nanorod has a surface coated with a metal oxide.

10. The ink composition of claim 9, wherein the metal oxide includes alumina, silica, or a combination thereof.

11. The ink composition of claim 1, wherein an amount of the semiconductor nanorod in the ink composition is in a range of about 0.01 wt % to about 10 wt %, based on a total amount of the ink composition.

12. The ink composition of claim 1, wherein the ink composition includes malonic acid, 3-amino-1,2-propanediol, a silane-based coupling agent, a leveling agent, a fluorine-based surfactant, or a combination thereof.

13. The ink composition of claim 1, wherein the ink composition is an ink composition for an electrophoresis device.

14. A layer manufactured using the ink composition of claim 1.

15. An electrophoresis device comprising the layer of claim 14.

16. A display device comprising the layer of claim 14.
